(19) United States
(12) Patent Application Publication
(10) Pub. No.: US 2026/0177101 A1
(43) Pub. Date: Jun. 25, 2026

(54) MOUNTING HOLE CAP AND MOTION GUIDE APPARATUS

(71) Applicant: THK CO., LTD., Tokyo (JP)

(72) Inventors: Masakazu Takahashi, Tokyo (JP); Katsuya Iida, Tokyo (JP); Soshi Miyahara, Tokyo (JP); Mitsumasa Wada, Tokyo (JP); Yuki Nakamura, Tokyo (JP)

(73) Assignee: THK CO., LTD., Tokyo (JP)

(21) Appl. No.: 18/855,491

(22) PCT Filed: Mar. 24, 2023
(86) PCT No.: PCT/JP2023/011724

§ 371 Date: Oct. 9, 2024

(30) Foreign Application Priority Data
Apr. 14, 2022 (JP) 2022-067021

(51) Int. Cl. F16C 29/06; B60N 2/07; B60N 2/235; H05K 7/14

(52) U.S. Cl. CPC F16C 29/065; B60N 2/0715; B60N 2/236; F16C 29/0609; F16C 29/063; F16C 29/0647; H05K 7/1489

(57) ABSTRACT

A mounting hole cap for a motion guide apparatus is provided which is capable of suppressing formation of burrs and securing a holding force and a removal force. A mounting hole cap of the present invention includes a lid portion and a fitting portion. The fitting portion includes a first fitting portion and a second fitting portion, which are placed in a circumferential direction. A slit is formed between the first fitting portion and the second fitting portion. The first fitting portion is formed with a protruding portion that comes into contact with an inner surface of a mounting hole. An outer diameter of the protruding portion of the first fitting portion is greater than an outer diameter of the second fitting portion.

### TECHNICAL FIELD

The present invention relates to a mounting hole cap for blocking a mounting hole in a rail of a motion guide apparatus, and a motion guide apparatus including the mounting hole cap.

### BACKGROUND ART

A motion guide apparatus is used to guide linear motion (rectilinear or curvilinear motion) of a movable body such as a table. The motion guide apparatus includes a rail mounted on a base, and a carriage assembled to the rail in such a manner as to be capable of linear motion. The carriage is provided with a circulation path that circulates a rolling element rolling between the rail and the carriage.

The rail is provided with a mounting hole into which a fastening member for fastening the rail to the base is inserted. If foreign matter such as dust and chips accumulates in the mounting hole, the foreign matter cannot be scraped out even with a sealing device provided to the carriage. If the foreign matter accumulated in the mounting hole enters the carriage, smooth rolling of the rolling element is hindered. Therefore, the mounting hole in the rail is blocked with a mounting hole cap.

A conventional mounting hole cap in Patent Literature 1 is known which has a disk-shaped cap body whose perimeter is provided with a plurality of projections. The cap is temporarily placed on a mounting hole and then driven into the mounting hole with, for example, a hammer. The projections of the cap are provided with interference. The cap is firmly fixed in the mounting hole with the interference of the projections.

Indexes for a force to fix the cap in the mounting hole include a holding force and a removal force. The holding force is a force required until the cap is embedded when a top surface of the cap is pressed down after the cap is driven into the mounting hole in the rail. If the holding force is weak, the cap is easily embedded, and foreign matter accumulates on the top surface of the cap. The removal force is a force required until the cap is removed from the mounting hole when the rail is flipped over and the cap is pressed in from the bottom side of the rail. If the removal force is weak, the cap easily comes out of the mounting hole when the carriage travels on the rail.

### CITATION LIST

### Patent Literature

Patent Literature 1: JP 2002-227838 A

### SUMMARY OF INVENTION

### Technical Problem

In the mounting hole cap for a motion guide apparatus, which is described in Patent Literature 1, the projections of the cap are provided with interference to secure the holding force and the removal force. However, when the cap is driven into the mounting hole, the projections are scraped, and burrs attached to the cap are formed on a top surface of the rail. It is necessary to cut off the burrs and remove them from the cap, and there are many caps. Therefore, this work takes a lot of time and effort. On the other hand, when the interference of the projections is reduced, the formation of burrs can be suppressed, but the holding force and removal force of the cap are now weakened. In this manner, since the suppression of formation of burrs and the securing of the holding force and removal force of the cap are in a contradictory relationship, there is a problem with the mounting hole cap in how to hold both points.

The present invention has been made in view of the above problem, and an object thereof is to provide a mounting hole cap for a motion guide apparatus, which is capable of suppressing formation of burrs and securing a holding force and a removal force.

### Solution to Problem

In order to solve the above problem, the present invention is a mounting hole cap for blocking a mounting hole in a rail of a motion guide apparatus, the mounting hole cap including: a lid portion; and a fitting portion, in which the fitting portion includes a first fitting portion and a second fitting portion placed in a circumferential direction, a slit is formed between the first fitting portion and the second fitting portion, the first fitting portion is formed with a protruding portion that comes into contact with an inner surface of the mounting hole, and an outer diameter of the protruding portion of the first fitting portion is greater than an outer diameter of the second fitting portion.

### Advantageous Effects of Invention

According to the present invention, the fitting portion of the mounting hole cap includes the first fitting portion and the second fitting portion defined by the slit, the first fitting portion is formed with the protruding portion that comes into contact with the inner surface of the mounting hole, and the outer diameter of the protruding portion of the first fitting portion is made greater than the outer diameter of the second fitting portion. Therefore, it is possible to make suppression of formation of burrs compatible with securing of a holding force and a removal force.

### BRIEF DESCRIPTION OF DRAWINGS

FIG. 1 is a perspective view of a motion guide apparatus.

FIG. 2 is a cross-sectional view of the motion guide apparatus.

FIG. 3 is a top-side perspective view of a cap of a first embodiment of the present invention.

FIG. 4 is a bottom-side perspective view of the cap of the embodiment.

FIG. 5 is detailed views of the cap of the embodiment (FIG. 5(a) is a cross-sectional view taken along line X-X of FIG. 5(b), FIG. 5(b) is a bottom view, and FIG. 5(c) is a cross-sectional view taken along line Y-Y of FIG. 5(b)).

FIG. 6 is an enlarged view of a part VI of FIG. 5.

FIG. 7 is a cross-sectional view of the cap, which has been temporarily placed in a mounting hole in a rail, of the embodiment.

FIG. 8 is a cross-sectional view of the cap, on which a pressing board has been placed, of the embodiment.

FIG. 9 is a cross-sectional view illustrating a dimensional relationship between the mounting hole in the rail and the cap of the embodiment.

FIG. 10 is a cross-sectional view of the cap, which has been driven into the mounting hole in the rail, of the embodiment.

FIG. 11 is an enlarged view of a part X of FIG. 10.

FIG. 12 is a bottom side perspective view of a cap of a second embodiment of the present invention.

FIG. 13 is a bottom-side perspective view of a cap of a third embodiment of the present invention.

### DESCRIPTION OF EMBODIMENTS

Embodiments of a mounting hole cap (hereinafter simply referred to as the cap) for a motion guide apparatus of the present invention are described in detail hereinafter with reference to the accompanying drawings. However, the cap of the present invention can be embodied in various forms and is not limited to the embodiments described in the description. The embodiments are provided with the intention of enabling those skilled in the art to fully understand the scope of the invention by fully disclosing the description.

### First Embodiment

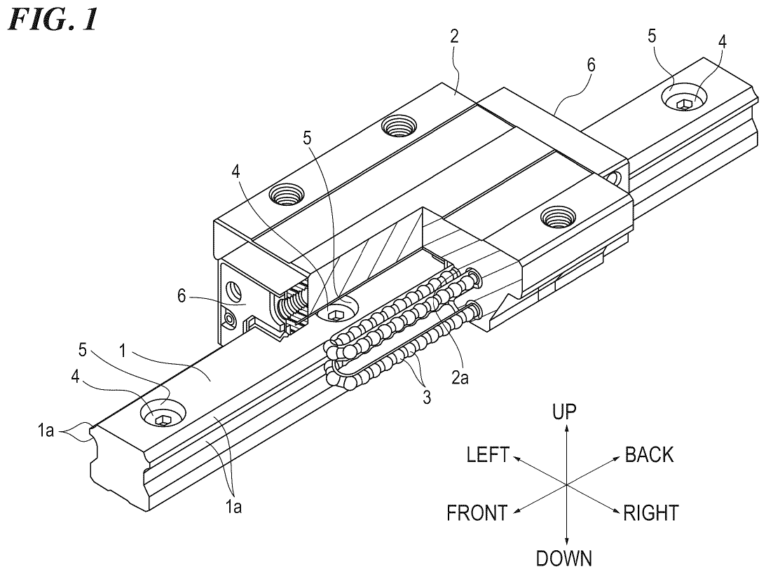

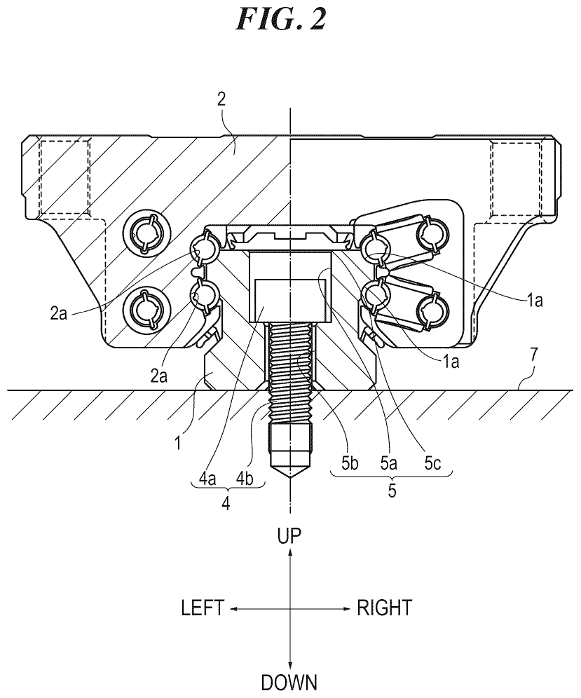

Firstly, the configuration of the motion guide apparatus is described. FIG. 1 illustrates a perspective view of the motion guide apparatus, and FIG. 2 illustrates a cross-sectional view of the motion guide apparatus. The motion guide apparatus includes a rail 1, and a carriage 2 that is assembled to the rail 1 via a plurality of rolling elements 3 such as balls or rollers in such a manner as to be capable of linear motion (rectilinear motion or curvilinear motion) in a length direction.

As illustrated in FIG. 1, the rail 1 extends along a straight or curved line. The rail 1 is formed with a rolling element rolling portion 1a on which the rolling elements 3 take rolling motion. The carriage 2 is formed with a rolling element rolling portion 2a facing the rolling element rolling portion 1a of the rail 1. The rolling elements 3 are interposed between the rolling element rolling portion 1a of the rail 1 and the rolling element rolling portion 2a of the carriage 2 in such a manner as to be capable of rolling motion. The carriage 2 is provided with a circulation path in which the rolling elements 3 are circulated. A reference sign 6 denotes a sealing device that removes foreign matter attached to the rail 1.

Note that hereafter, for convenience of description, directions relative to the rail 1 placed on a horizontal plane as viewed in a length direction of the rail 1, that is, directions of up-down, left-right, and front-back in FIGS. 1 and 2, are used to describe the configuration of the motion guide apparatus. Naturally, the placement of the motion guide apparatus is not limited to the above, and the rail 1 may be mounted on a vertical surface, or the motion guide apparatus may be flipped vertically.

A top surface of the rail 1 is formed with a plurality of mounting holes 5 at regular intervals in the length direction. A bolt 4, which is a fastening member for fastening the rail 1 to a base 7, is inserted into each of the mounting holes 5.

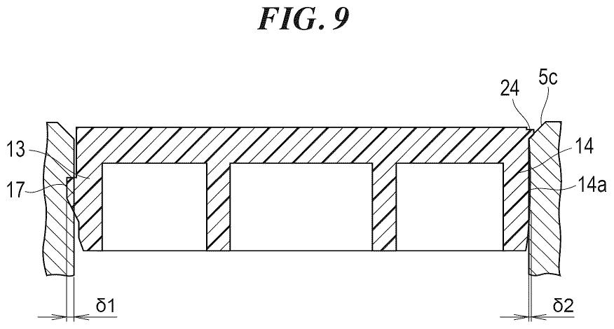

As illustrated in FIG. 2, the each of the mounting holes 5 includes a counterbore portion 5a in which a head portion 4a of the bolt 4 is seated, and an insertion hole 5b into which a threaded portion 4b of the bolt 4 is inserted. A chamfer 5c (refer also to FIG. 9) is provided on an inner peripheral edge of an opening portion of each of the counterbore portions 5a. The height of the counterbore portions 5a is greater than the height of the head portions 4a of the bolts 4 in such a manner that the bolts 4 are completely buried in the mounting holes 5.

FIGS. 1 and 2 illustrate a state in which the bolts 4 have been passed through the mounting holes 5 in the rail 1 and the bolts 4 have been fastened to the base 7. The mounting holes 5 are then blocked with caps 8.

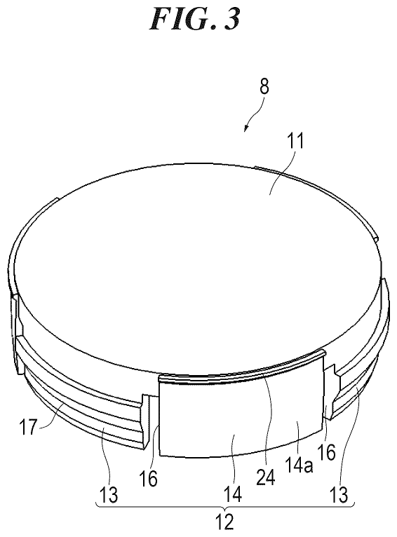

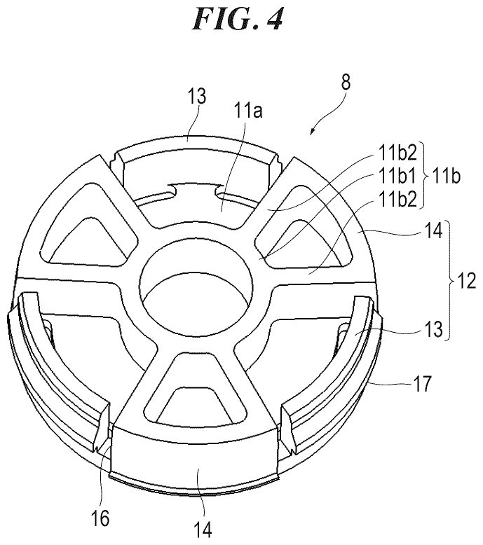

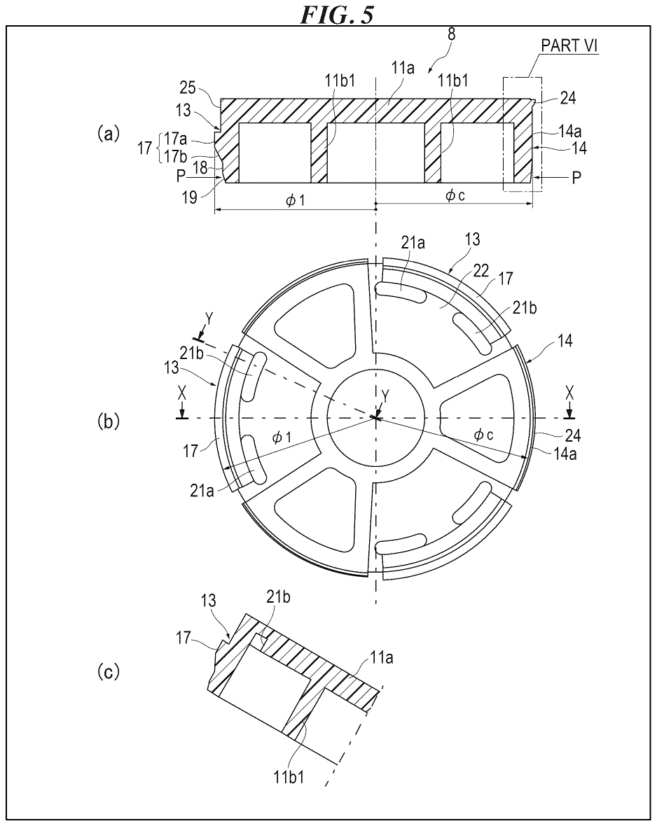

FIG. 3 illustrates a top-side perspective view of the cap 8 of the first embodiment of the present invention, and FIG. 4 illustrates a bottom-side perspective view. FIG. 5 illustrates detailed views including a cross-sectional view and a bottom view of the cap 8.

As illustrated in FIG. 3, the cap 8 includes a lid portion 11 and a fitting portion 12. The fitting portion 12 is formed integrally with the lid portion 11. A top surface of the cap 8 is formed on the lid portion 11. A side surface of the cap 8 is formed on the fitting portion 12. The cap 8 is manufactured by, for example, resin injection molding.

As illustrated in FIG. 4, the lid portion 11 includes an approximately disk-shaped top plate portion 11a, and a reinforcing rib 11b provided on an undersurface of the top plate portion 11a. The reinforcing rib 11b includes an annular rib 11b1 formed in an annular fashion around the center of the top plate portion 11a, and a radial rib 11b2 extending radially from the annular rib 11bl. The radial rib 11b2 is connected to both ends of each of second fitting portions 14 in a circumferential direction. The annular rib 11b1 reinforces the top plate portion 11a, and the radial rib 11b2 reinforces the second fitting portions 14. The annular rib 11b1 and the radial rib 11b2 extend from the undersurface of the top plate portion 11a to an undersurface of the fitting portion 12 (refer to FIG. 5(a)).

As illustrated in FIG. 3, the fitting portion 12 extends downward from an outer peripheral portion of the lid portion 11. The fitting portion 12 has an approximately cylindrical shape. The fitting portion 12 includes a plurality of first fitting portions 13 and a plurality of the second fitting portions 14, which are placed in the circumferential direction. The first fitting portions 13 and the second fitting portions 14 are alternately placed in the circumferential direction. The second fitting portions 14 are placed diagonally to the first fitting portions 13. Note that it is simply required to provide at least one first fitting portion 13 and at least one second fitting portion 14.

Slits 16 are formed between the first fitting portions 13 and the second fitting portions 14. The first fitting portions 13 and the second fitting portions 14 are defined by the slits 16. The slits 16 extend axially from a lower end of the fitting portion 12 to the top plate portion 11a.

Each of the first fitting portions 13 is formed with a protruding portion 17 that comes into contact with an inner surface of the mounting hole 5 in the rail 1. The protruding portions 17 extend in the circumferential direction. As illustrated in FIG. 5(a), an outer surface of each of the protruding portions 17 is formed with a cylindrical first parallel portion 17a substantially parallel to the inner surface of the mounting hole 5. A guide slope 17b that guides the protruding portion 17 in such a manner that the protruding portion 17 enters the mounting hole 5 is formed below the first parallel portion 17a of the protruding portion 17. A cylindrical second parallel portion 18 substantially parallel to the inner surface of the mounting hole 5 is formed below the protruding portion 17 of the each of the first fitting portions 13. A lower end portion of the each of the first fitting portions 13 is formed with a guide slope 19 that guides the first fitting portion 13 in such a manner that the first fitting portion 13 enters the mounting hole 5. A cylindrical third parallel portion 25 substantially parallel to the inner surface of the mounting hole 5 is formed above the protruding portion 17 of the each of the first fitting portions 13.

As illustrated in FIG. 3, a flange 24 that covers the chamfer 5c at the inner peripheral edge of the opening portion of the mounting hole 5 is formed on upper portions of the second fitting portions 14. The flange 24 is formed only on the upper portions of the second fitting portions 14, and is not formed on upper portions of the first fitting portions 13. In other words, the flange 24 is formed discontinuously around the cap 8.

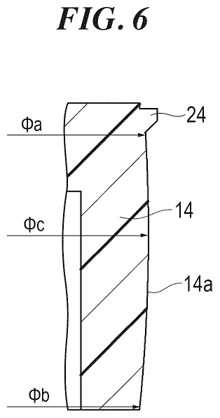

As illustrated in FIGS. 5(a) and 5(b), an outer diameter Φ1 of the protruding portions 17 of the first fitting portions 13 is greater than an outer diameter Φc of the second fitting portions 14, that is, the outer diameter Φc of outer surfaces 14a of the second fitting portions 14 below the flange 24. The outer surfaces 14a of the second fitting portions 14 below the flange 24 are formed in a curved shape like a barrel whose middle portion in an up-and-down direction bulges out most. As illustrated in FIG. 6, the outer surfaces 14a of the second fitting portions 14 have a curved shape in a vertical cross section. The outer diameter Φc of the middle portions of the outer surfaces 14a of the second fitting portions 14 is greater than an outer diameter Φa of upper portions thereof and an outer diameter Φb of lower portions thereof. The maximum diameter Φc of the outer surfaces 14a is the outer diameter Φc of the second fitting portions 14.

The second fitting portions 14 are formed in such a manner as to be more resistant to the inward bending of the cap 8 than the first fitting portions 13. As illustrated in FIG. 5(a), the bending amount of lower end portions of the second fitting portions 14 at the time when a load P toward the center of the cap 8 is applied to the lower end portions of the second fitting portions 14 is less than the bending amount of the lower end portions of the first fitting portions 13 at the time when the load P toward the center of the cap 8 is applied to the lower end portions of the first fitting portions 13.

As illustrated in FIG. 5(b), arc-shaped grooves 21a and 21b that make the first fitting portions 13 more easily bendable than the second fitting portions 14 are formed in the undersurface of the top plate portion 11a of the lid portion 11 along the first fitting portions 13. Beams 22 that suppress deformation of the top plate portion 11a are formed each between the arc-shaped grooves 21a and 21b.

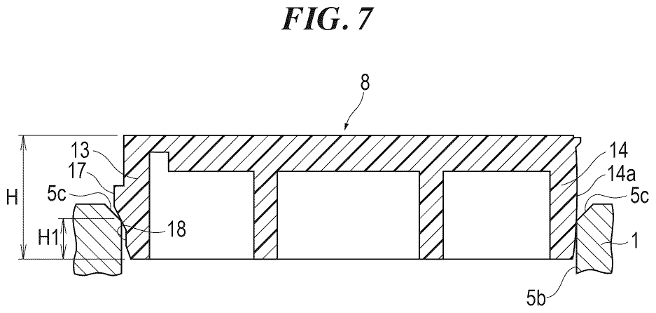

A process of driving the cap 8 into the mounting hole 5 is described below. Firstly, as illustrated in FIG. 7, the cap 8 is temporarily placed in the mounting hole 5. At this point in time, the protruding portions 17 of the first fitting portions 13 of the cap 8 are caught on the chamfer 5c of the mounting hole 5. An amount H1 of entry of the cap 8 into the mounting hole 5, that is, the amount H1 of entry of the cap 8 below the chamfer 5c is equal to or more than 25%, desirably equal to or more than 30%, of a thickness (H) of the cap 8 in the up-and-down direction.

When the cap 8 is temporarily placed in the mounting hole 5, then the second parallel portions 18 of the first fitting portions 13 of the cap 8 enter the mounting hole 5, and the outer surfaces 14a of the second fitting portions 14 of the cap 8 come into contact with the mounting hole 5. Combined with H1 being 25%, it is possible to prevent the cap 8 that has been temporarily placed from being inclined, and it is possible to improve the stability of the cap 8.

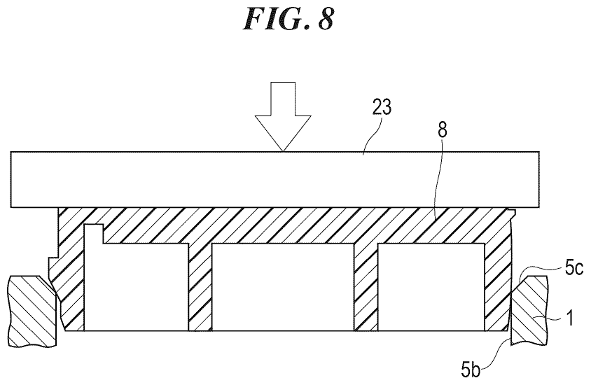

Next, as illustrated in FIG. 8, a pressing board 23 is placed on the cap 8, and the pressing board 23 is tapped with a hammer. FIG. 9 illustrates a dimensional relationship between the cap 8 and the mounting hole 5 before bending deformation. When the cap 8 is driven into the mounting hole 5, then the protruding portions 17 of the first fitting portions 13 are press-fitted into the mounting hole 5, and also the outer surfaces 14a of the second fitting portions 14 are press-fitted into the mounting hole 5. The cap 8 is press-fitted into the mounting hole 5 with interferences 61 and 62. Therefore, the holding force and the removal force can be secured.

Here, the outer diameter Φ1 of the protruding portions 17 of the first fitting portions 13 is greater than the outer diameter Φc of the outer surfaces 14a of the second fitting portions 14. Therefore, the interference δ1 of the first fitting portions 13 is greater than the interference δ2 of the second fitting portions 14. The first fitting portions 13 are press-fitted into the mounting hole 5 with the interference δ1 greater than that of the second fitting portions 14. Note that there may be a slight gap between each of the outer surfaces 14a of the second fitting portions 14 and the inner surface of the mounting hole 5, depending on the dimensional tolerance of the mounting hole 5, and it is simply required to have the interference δ1 at least between each of the first fitting portions 13 and the mounting hole 5.

As illustrated in FIG. 9, when the cap 8 is driven into the mounting hole 5, then the flange 24 of the second fitting portions 14 is placed on the chamfer 5c of the mounting hole 5. Therefore, the holding force can be secured by the shear force of the flange 24.

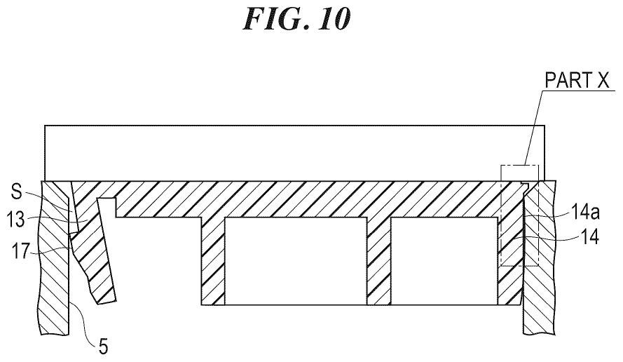

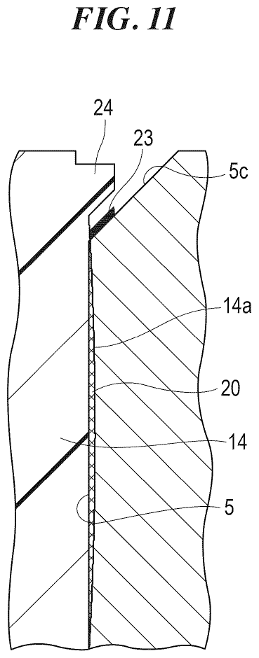

As illustrated in FIG. 10, when the cap 8 is press-fitted into the mounting hole 5, then the protruding portions 17 of the first fitting portions 13 come into contact with the inner surface of the mounting hole 5, and the first fitting portions 13 bend. Therefore, it is possible to suppress formation of burrs on the first fitting portions 13. Since the second fitting portions 14 are press-fitted into the mounting hole 5 with the interference δ2 less than that of the first fitting portions 13, a portion 20 (an area indicated by cross lines in the drawing) that becomes a burr on the second fitting portion 14 is small as illustrated in an enlarged view of FIG. 11, and the burr is hardly formed. Even if a burr is formed, the outer surfaces 14a of the second fitting portions 14 are formed in a curved shape like a barrel. Therefore, a burr 23 enters between the flange 24 of the cap 8 and the chamfer 5c of the mounting hole 5. Therefore, the burr 23 is prevented from coming out onto the top surface of the rail 1.

The configuration and driving process of the cap 8 of the embodiment have been described above. The cap 8 of the embodiment exerts the following effects:

The fitting portion 12 of the cap 8 includes the first fitting portions 13 and the second fitting portions 14, which are defined by the slits 16, each of the first fitting portions 13 is formed with the respective protruding portion 17 that comes into contact with the inner surface of the mounting hole 5, and the outer diameter Φ1 of the protruding portions 17 are made greater than the outer diameter Φc of the second fitting portions 14. Therefore, it is possible to make the suppression of formation of burrs compatible with securing the holding force and the removal force.

Since the flange 24 covering the chamfer 5c of the opening portion of the mounting hole 5 is formed on the upper portions of the second fitting portions 14, the holding force can be secured.

Since the outer surfaces 14a of the second fitting portions 14 are formed in a curved shape whose middle portion in the up-and-down direction bulges out most, it is possible to suppress the formation of burrs on the second fitting portions 14 in addition to that the second fitting portions 14 secure the holding force and the removal force.

Since the flange 24 is not formed on the upper portions of the first fitting portions 13, it is possible to prevent generation of undercuts between the flange 24 and the protruding portions 17 and to easily resin-mold the cap 8. Moreover, even if burrs are formed on the protruding portions 17 of the first fitting portions 13, it is possible to keep the burrs in spaces s (refer to FIG. 10) above the protruding portions 17, or to move the burrs into the cap 8 via the slits 16. Therefore, it is possible to prevent the burrs from coming out. Note that the spaces s are formed with a size that does not allow the burrs to come out and allows the burs to stay in the spaces s.

Since the lid portion 11 is provided with the reinforcing rib 11b connected to the second fitting portions 14, it is possible to make the second fitting portions 14 resistant to bending.

Since the entry amount (H1) at the time when the cap 8 is temporarily placed in the mounting hole 5 is equal to or more than 25% of the thickness (H) of the cap 8 in the up-and-down direction, the stability of the cap 8 can be improved.

### Second Embodiment

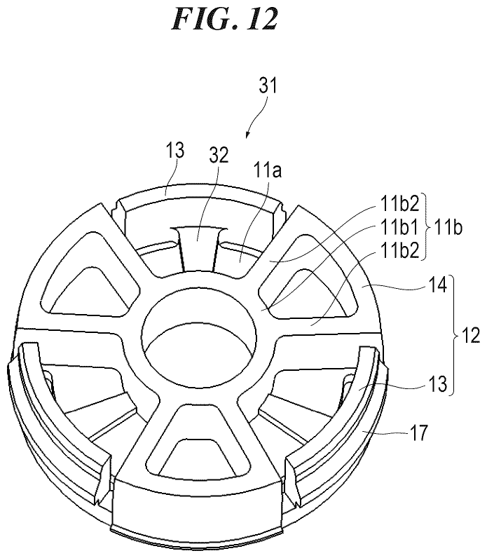

FIG. 12 illustrates a bottom side perspective view of a cap 31 of a second embodiment of the present invention. The cap 31 also includes a lid portion 11 and a fitting portion 12. A reference sign 11a denotes a top plate portion of the lid portion 11, reference signs 11b1 and 11b2 denote reinforcing ribs of the lid portion 11, a reference sign 13 denotes first fitting portions, a reference sign 17 denotes protruding portions of the first fitting portions, and a reference sign 14 denotes second fitting portions. Since these configurations are substantially the same as those of the cap 8 of the first embodiment, the same reference signs are assigned to the configurations, and descriptions thereof are omitted.

In terms of the cap 8 of the first embodiment, the beams 22 (refer to FIG. 5(b)) that suppress deformation of the top plate portion 11a of the lid portion 11 is formed only between the grooves 21a and 21b. However, in terms of the cap 31 of the second embodiment, beams 32 are not only formed between the grooves 21a and 21b, but also extend radially from the annular rib 11b1 to the first fitting portions 13. To further suppress the deformation of the top plate portion 11a, the beams 32 may be formed in this manner. However, when the beams 32 are formed all over the undersurface of the top plate portion 11a, the first fitting portions 13 become resistant to bending, and burrs may be formed. Therefore, it is desirable to form the beams 32 by increasing the thickness of only parts of the undersurface of the top plate portion 11a.

### Third Embodiment

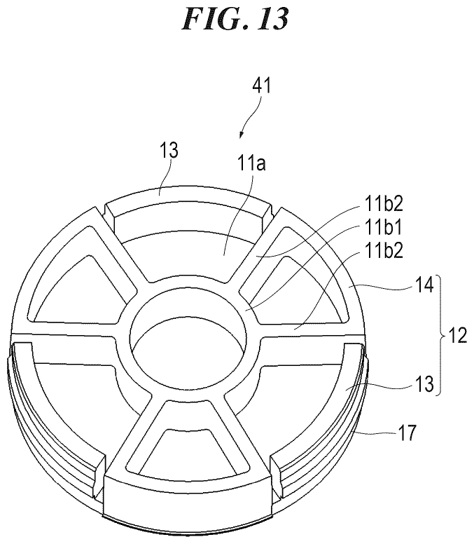

FIG. 13 illustrates a bottom-side perspective view of a cap 41 of a third embodiment of the present invention. The cap 41 also includes a lid portion 11 and a fitting portion 12. Since the configurations of a top plate portion 11a, reinforcing ribs 11b1 and 11b2, first fitting portions 13, protruding portions 17, and second fitting portions 14 of the lid portion 11 are substantially the same as those of the cap 8 of the first embodiment, the same reference signs are assigned to the configurations, and descriptions thereof are omitted.

In terms of the cap 8 of the first embodiment, the grooves 21a and 21b are formed in the undersurface of the top plate portion 11a to facilitate the bending of the first fitting portions 13. On the other hand, in terms of the cap 41 of the third embodiment, a groove is not formed, and the undersurface of the top plate portion 11a is flat. When the dimensions of the mounting hole 5 are large, the length of the first fitting portions 13 in the up-and-down direction will also be long, which facilitates the bending of the first fitting portions 13. Therefore, the first fitting portions 13 can be bent without forming the grooves 21a and 21b in the undersurface of the top plate portion 11a.

Note that the present invention is not limited to concretization of the above embodiments, and can be concretized in other embodiments within the scope that does not change the purport of the present invention.

For example, in the above embodiments, the protruding portions formed on the first fitting portions extend in the circumferential direction, but may extend in an axial direction. Moreover, each of the protruding portions may include one or more projections.

In the above embodiments, a flange is not provided on the upper portions of the first fitting portions, but a flange may be provided on the upper portions of the first fitting portions.

The present description is based on Japanese Patent Application No. 2022-067021 filed on Apr. 14, 2022. The entire contents thereof are included herein.

### REFERENCE SIGNS LIST

1 Rail
2 Carriage
4 Bolt (fastening member)
5 Mounting hole
8 Mounting hole cap
11 Lid portion
11a Top plate portion
11b Reinforcing rib
12 Fitting portion
13 First fitting portion
14 Second fitting portion
14a Outer surface of second fitting portion
16 Slit
17 Protruding portion
24 Flange
31 Cap
41 Cap
Φ1 Outer diameter of protruding portion of first fitting portion
Φc Outer diameter of second fitting portion

1. A mounting hole cap for blocking a mounting hole in a rail of a motion guide apparatus, the mounting hole cap comprising:
a lid portion; and
a fitting portion, wherein
the fitting portion includes a first fitting portion and a second fitting portion placed in a circumferential direction,
a slit is formed between the first fitting portion and the second fitting portion,
the first fitting portion is formed with a protruding portion that comes into contact with an inner surface of the mounting hole, and
an outer diameter of the protruding portion of the first fitting portion is greater than an outer diameter of the second fitting portion.

2. The mounting hole cap according to claim 1, wherein a flange that covers a chamfer of an inner peripheral edge of an opening portion of the mounting hole is formed on an upper portion of the second fitting portion.

3. The mounting hole cap according to claim 1, wherein an outer surface of the second fitting portion is formed in a curved shape whose middle portion in an up-and-down direction bulges out most.

4. The mounting hole cap according to claim 2, wherein the flange is not formed on an outer surface of an upper portion of the first fitting portion.

5. The mounting hole cap according to claim 1, wherein the lid portion includes a top plate portion and a reinforcing rib provided on an undersurface of the top plate portion and connected to the second fitting portion.

6. The mounting hole cap according to claim 1, wherein upon the mounting hole cap being temporarily placed in the mounting hole, an entry amount (H1) of the mounting hole cap into the mounting hole is equal to or more than 25% of a thickness (H) of the mounting hole cap in the up-and-down direction.

7. A motion guide apparatus comprising:
the mounting hole cap according to claim 1;
a rail; and
a carriage assembled to the rail and configured to be movable relative to the rail.

8. The mounting hole cap according to claim 2, wherein an outer surface of the second fitting portion is formed in a curved shape whose middle portion in an up-and-down direction bulges out most.

9. The mounting hole cap according to claim 2, wherein the lid portion includes a top plate portion and a reinforcing rib provided on an undersurface of the top plate portion and connected to the second fitting portion.

10. The mounting hole cap according to claim 2, wherein upon the mounting hole cap being temporarily placed in the mounting hole, an entry amount (H1) of the mounting hole cap into the mounting hole is equal to or more than 25% of a thickness (H) of the mounting hole cap in the up-and-down direction.

11. A motion guide apparatus comprising:
the mounting hole cap according to claim 2;
a rail; and
a carriage assembled to the rail and configured to be movable relative to the rail.
